(19) United States
(12) Patent Application Publication
(10) Pub. No.: US 2002/0088542 A1
(43) Pub. Date: Jul. 11, 2002

(54) Plasma processing apparatus

(76) Inventors: Kazuyasu Nishikawa, Tokyo (JP); Hiroki ootera, Tokyo (JP); Masakazu Taki, Tokyo (JP); Kenji Shintani, Tokyo (JP); Shingo Tomohisa, Tokyo (JP); Tatsuo Oomori, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/496,254

(22) Filed: Feb. 1, 2000

(30) Foreign Application Priority Data
Jul. 7, 1999 (JP) 11-192932

(51) Int. Cl. C23F 1/02; C23C 16/00; C23C 16/505

(52) U.S. Cl. 156/345.29; 118/723 I; 118/723 IR; 156/345.34; 156/345.48

(57) ABSTRACT

A plasma processing apparatus includes a reaction chamber for processing a workpiece with plasma which is generated by using one or more gases, a gas supplying means which pulsatively supplies the gases to the reaction chamber, and an exhaust means for exhausting the reaction chamber, wherein a gas supplying direction by said gas supplying means is arranged to correspond with an exhausting direction by said exhausting means.

### BACKGROUND OF THE INVENTION

1. Field of the Invention

The present invention relates to a plasma processing apparatus for deposition of a thin film onto a surface of a workpiece or for etching a surface of a workpiece.

2. Description of the Related Art

Conventionally, as an apparatus for processing a workpiece, for example, a substrate or a semiconductor wafer (hereinafter, also referred to as a “wafer”) using plasma in a processing chamber, a parallel plate type plasma processing apparatus using radio frequency (RF) plasma has been widely utilized. Such type of plasma processing apparatus has a constitution that plasma is generated between its parallel plate electrodes by applying radio frequency voltage to one or both of the electrodes, thereby allowing ions become incident on the surface of the workpiece to be processed by an RF self-bias voltage between the plasma and the workpiece; and then a processing, for example, etching processing are performed.

However, according to the above mentioned parallel plate type plasma processing apparatus, it was not easy to achieve fine-pattern processing and low-damage which were required for the production of semiconductor devices as the integrated density thereof has been increased and the performance thereof has been enhanced. That is, in order to achieve such a process, it is important to generate and control a low-pressure, high-density plasma. Such plasma is required to have a uniform density over a large area so that it may process a wafer having a large diameter.

To solve the above requirements, various kinds of plasma sources and processing methods have been proposed and applied to the semiconductors processing. Among those, a plasma processing apparatus shown in FIG. 14, which uses a pulse gas valve for pulsatively supplying one or more processing gases to a reaction container and is disclosed in Japanese Patent Kokai Publication No. 263353/1995, has been favorably prospected for application to semiconductor processing field. It is because such a plasma processing apparatus enables to decrease the plasma temperature by utilizing a pressure difference between the plasma generating chamber and the processing chamber. In FIG. 14, reference numeral 2 designates a processing chamber wherein a workpiece, for example a wafer 8 is processed with plasma, reference numeral 3 designates a plasma generating chamber wherein plasma is generated, and reaction chamber I consists of these two chambers 2 and 3. Reference numeral 4 designates a partition plate for partitioning the processing chamber 2 from the plasma generating chamber 3, reference numeral 5 designates holes which are provided in the partition plate 4 and makes the processing chamber 2 in connection with the plasma generating chamber 3, reference numeral 6 designates a exhaust port, reference numeral 7 designates a stage, and reference numeral 9 designates a pulse gas valve which pulsatively supplies one or more gases to the plasma generating chamber 3. Reference numeral 10 designates a drive means for the pulse gas valve 9, reference numeral 11 designates a gas introducing line, reference numeral 12 designates a wave guide, reference numeral 1.3 designates a window for introducing microwave, and reference numeral 14 designates a magnetic field coil.

In this plasma processing apparatus, the plasma generated in the plasma generating chamber 3 is supplied to the processing chamber 2 through holes 5 in the partition plate 4. In this case, the plasma is introduced into the processing chamber 2 as a supersonic free jet by the pressure difference between the plasma generating chamber 3 and the processing chamber 2, and simultaneously the temperature of the plasma decreased, so that an etching processing with anisotropic profile and low-damage may be performed. Further, it is possible to process uniformly the wafer having a large diameter by selecting the sizes and the arrangement of the holes 5.

According to the above-mentioned plasma processing apparatus using pulse gas valve, the processing gases instantaneously diffuses throughout the reaction chamber 1 as a supersonic free jet due to a pressure difference caused by closing and opening operation of the pulse gas valve 9, and then become incident on the surface of wafer 8. Therefore, it was contemplated that a uniformalization of the processing rate of wafer 8 and the processed profile over the wafer 8 were achieved without deviation of gas flow and pressure in the reaction chamber 1.

However, according to the present inventors' further detailed examination as to the gas flow, it was found that there is a possibility to cause a problem that uniform processing rate and processed profile over the wafer 8 are not always achieved. Such a problem may be caused by a deviation of flow of the processing gases and reaction product, for example, in the case just before the pulse gas valve 9 is opened, in the case when a repeating period of closing and opening of the pulse gas valve 9 is short, and in the case when the pressure difference is too small to sufficiently produce a supersonic free jet, for example when a closing time of the pulse gas valve 9 is too short. In other word, under a condition where a supersonic free jet is satisfied, processing of wafer 8 is independent of the arranging positions of the pulse gas valve 9 and exhaust port 6. However, under the condition where a supersonic free jet is not satisfied, the gas flow and pressure in the reaction chamber 1 may be deviated depending on the arranging positions of the pulse gas valve 9 and exhaust port 6, which may become a problem to affect the processability of wafer 8.

### SUMMARY OF THE INVENTION

In order to solve the above-mentioned problems of the prior art, it is an object of the present invention to achieve uniformalization of the processing rate and the processed profile over the wafer under a condition even when a supersonic free jet is not formed in the plasma processing apparatus, which is provided with a means for pulsatively supplying one or more gases into the reaction chamber.

In a first aspect of the present invention, the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein a gas supplying direction by said gas supplying means is arranged to correspond with an exhausting direction by said exhausting means.

In a second aspect of the present invention, the plasma processing apparatus has, in addition to the constitution according to the first aspect of the present invention above mentioned, a constitution that, when observed from a direction perpendicular to a face to be processed of the workpiece, the gas supplying direction by said gas supplying means directs to a center of the reaction chamber, and the exhausting means are arranged in the reaction chamber so that an assumed straight line extending from the center of the reaction chamber to the exhausting means is oriented at an angle from −45 degree to +45 degree relative to a line from the gas supplying means to the center of the reaction chamber and the exhausting direction by the exhausting means from the center of the reaction chamber is also oriented at the same angle as above.

In a third aspect of the present invention, the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein the shape of the reaction chamber is axially symmetrical with respect to an central axis of the reaction chamber, the gas supplying means are arranged on the central axis or at axially symmetrical positions with respect to the central axis of the reaction chamber, and the exhaust means are also arranged at axially symmetrical positions with respect to the central axis of the reaction chamber.

In a fourth aspect of the present invention, the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein the amount of the gases supplied by the gas supplying means is set relatively small in the proximity of the exhaust means and the amount of the gases supplied by the gas supplying means is increased at a position where its distance from the exhaust means increases.

In a fifth aspect of the present invention, the plasma processing apparatus has, in addition to the constitution according to the fourth aspect of the present invention above mentioned, a constitution that a number of the gas supplying means is set relatively small in the proximity of the exhaust means and the number of the gas supplying means is increased at a position where its distance from the exhaust means increases.

In a sixth aspect of the present invention, the plasma processing apparatus has, in addition to the constitution according to the fourth aspect of the present invention above mentioned, a constitution that the gas flow rate is set at a relatively small value in the proximity of the exhaust means and the value of the gas flow rate is increased at a position where its distance from the exhaust means increases.

In a seventh aspect of the present invention, the plasma processing apparatus comprises a reaction chamber for processing a workpiece with plasma which is generated by using one or more gases, a gas supplying means which pulsatively supplies the gases to the reaction chamber, an exhaust means for exhausting the reaction chamber, a partition plate which partitions the plasma generating chamber wherein plasma is generated from the processing chamber wherein the workpiece is processed with the plasma, and holes which are provided in the partition plate and make the processing chamber in connection with the plasma generating chamber, wherein at least one of the number and the size of the holes is changed depending on the distance thereof from the exhausting means, thereby an opening ratio of the holes being set at a relatively small figure in the proximity of the exhaust port and the figure thereof being relatively increased at a position where its distance from the exhaust means relatively increases.

In a eighth aspect of the present invention, the plasma processing apparatus has, in addition to the constitution according to the seventh aspect of the present invention above mentioned, a constitution that a number of the holes is set at a relatively small figure in the proximity of the exhaust port and the number of the holes is relatively increased at a position where its distance from the exhaust means relatively increases.

In a ninth aspect of the present invention, the plasma processing apparatus has, in addition to the constitution according to the seventh aspect of the present invention above mentioned, a constitution that a size of the hole is set at a relatively small figure in the proximity of the exhaust port and the size of the hole is relatively increased at a position where its distance from the exhaust means relatively increases.

According to the first aspect of the present invention, since it has a constitution that the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein a gas supplying direction by said gas supplying means is arranged to correspond with an exhausting direction by said exhausting means, even if a supersonic free jet is not formed, the gas flow and the pressure from the gas supplying means to the exhaust ports may be unified, so that a uniform processing over the workpiece can be achieved.

According to the second aspect of the present invention, since, in addition to the constitution according to the first aspect of the present invention above mentioned, it has a constitution that, when observed from a direction perpendicular to a face to be processed of the workpiece, the gas supplying direction by said gas supplying means directs to a center of the reaction chamber, and the exhausting means are arranged in the reaction chamber 1 so that a line extending from the center of the reaction chamber 1 to the exhausting means is oriented at an angle from −45 degree to +45 degree relative to a line from the gas supplying means to the center of the reaction chamber 1 and the exhausting direction by the exhausting means from the center of the reaction chamber 1 is also oriented at the same angle as above, even if the mounting positions of the gas supplying means and the exhausting means are limited in the apparatus due to a requirement of the constitution of the apparatus, a uniform processing over the workpiece may be achieved as long as the arrangement of the exhausting means and the exhausting direction are set within the angle above mentioned.

According to the third aspect of the present invention, since it has a constitution that the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein the shape of the reaction chamber is axially symmetrical with respect to an central axis of the reaction chamber, the gas supplying means are arranged on the central axis or at axially symmetrical positions with respect to the central axis of the reaction chamber, and the exhaust means are also arranged at axially symmetrical positions with respect to the central axis of the reaction chamber, even if a supersonic free jet is not formed, the gas flow and the pressure from the gas supplying means to the exhaust ports may be unified, so that a uniform processing over the workpiece can be achieved.

According to the fourth aspect of the present invention, since it has a constitution that the plasma processing apparatus comprises a reaction chamber for processing a workpiece with plasma which is generated by using one or more gases, a gas supplying means which pulsatively supplies the gases to the reaction chamber, and an exhaust means for exhausting the reaction chamber, wherein the amount of the gases supplied by the gas supplying means is set relatively small in the proximity of the exhaust means and the amount of the gases supplied by the gas supplying means is increased at a position where its distance from the exhaust means increases, even if a supersonic free jet is not formed, the deviation or unevenness of pressure and gas flow within the reaction chamber can be prevented, so that a uniform processing over the workpiece can be achieved.

According to the fifth aspect of the present invention, since, in addition to the constitution according to the fourth aspect of the present invention above mentioned, it has a constitution that a number of the gas supplying means is set relatively small in the proximity of the exhaust means and the number of the gas supplying means is increased at a position where its distance from the exhaust means increases, the constitution according to the fourth aspect can be achieved with a simple constitution and a uniform processing over the workpiece can be achieved.

According to the sixth aspect of the present invention, since, in addition to the constitution according to the fourth aspect of the present invention above mentioned, it has a constitution that the gas flow rate is set at a relatively small figure in the proximity of the exhaust means and the figure of the gas flow rate is increased at a position where its distance from the exhaust means increases, even if a plurality of gas supplying means are used and each of them are arranged within the reaction chamber at optional position respectively, the constitution according to the fourth aspect can be achieved and a uniform processing over the workpiece can be achieved.

According to the seventh aspect of the present invention, since it has a constitution that the plasma processing apparatus comprises a reaction chamber for processing a workpiece with plasma which is generated by using one or more gases, a gas supplying means which pulsatively supplies the gases to the reaction chamber, an exhaust means for exhausting the reaction chamber, a partition plate which partitions the plasma generating chamber wherein plasma is generated from the processing chamber wherein a workpiece is processed with the plasma, and holes which are provided in the partition plate and make the processing chamber in connection with the plasma generating chamber, wherein at least one of the number and the size of the holes is changed depending on the distance thereof from the exhausting means, thereby an opening ratio of the holes being set at a relatively small figure in the proximity of the exhaust port and the figure thereof being relatively increased at a position where its distance from the exhaust means relatively increases, even if a supersonic free jet is not formed, a uniform rate or transport speeds of the plasma and the gases from the plasma generating chamber to the processing chamber can be achieved, so that deviation or unevenness of pressure and gas flow within the reaction chamber 1 may be prevented. Accordingly, a uniform processing over the workpiece may be achieved.

According to the eighth aspect of the present invention, since, in addition to the constitution according to the seventh aspect of the present invention above mentioned, it has a constitution that a number of the holes is set at a relatively small figure in the proximity of the exhaust port and the number of the holes is relatively increased at a position where its distance from the exhaust means relatively increases, the constitution according to the seventh aspect can be achieved with a simple constitution and a uniform processing over the workpiece can be achieved.

According to the ninth aspect of the present invention, since, in addition to the constitution according to the seventh aspect of the present invention above mentioned, it has a constitution that the constitution according to the seventh aspect can be achieved with a simple constitution and a uniform processing over the workpiece can be achieved.

### BRIEF DESCRIPTION OF THE DRAWINGS

FIG. 1 is a schematic cross-sectional view of a plasma processing apparatus according to a first embodiment of the present invention;

FIG. 2 is another schematic cross-sectional view of the plasma processing apparatus according to the first embodiment of the present invention;

FIG. 3 is the other schematic cross-sectional view of the plasma processing apparatus according to the first embodiment of the present invention;

FIG. 4 is a schematic cross-sectional view of a plasma processing apparatus according to a second embodiment of the present invention;

FIG. 5 is a schematic plan view showing an example of the constitution according to the second embodiment of the present invention.

FIG. 6 is a schematic cross-sectional view of a plasma processing apparatus wherein a connecting position of a pulse gas valve is changed in comparison to the second embodiment of the present invention;

FIG. 7 is a schematic plan view showing another example of the constitution of a second embodiment of the present invention.

FIG. 8 is a schematic cross-sectional view of a plasma processing apparatus according to a third embodiment of the present invention;

FIG. 9 is a schematic cross-sectional view of a plasma processing apparatus according to a fourth embodiment of the present invention;

FIG. 10 is a schematic cross-sectional view of a plasma processing apparatus according to a fifth embodiment of the present invention;

FIG. 11 is a schematic enlarged plan view showing the partition plate according to the fifth embodiment of the present invention;

FIG. 12 is a schematic cross-sectional view of a plasma processing apparatus according to a sixth embodiment of the present invention;

FIG. 13 is a schematic enlarged plan view showing the partition plate according to the sixth embodiment of the present invention; and

FIG. 14 is a schematic cross-sectional view of a prior art plasma processing device.

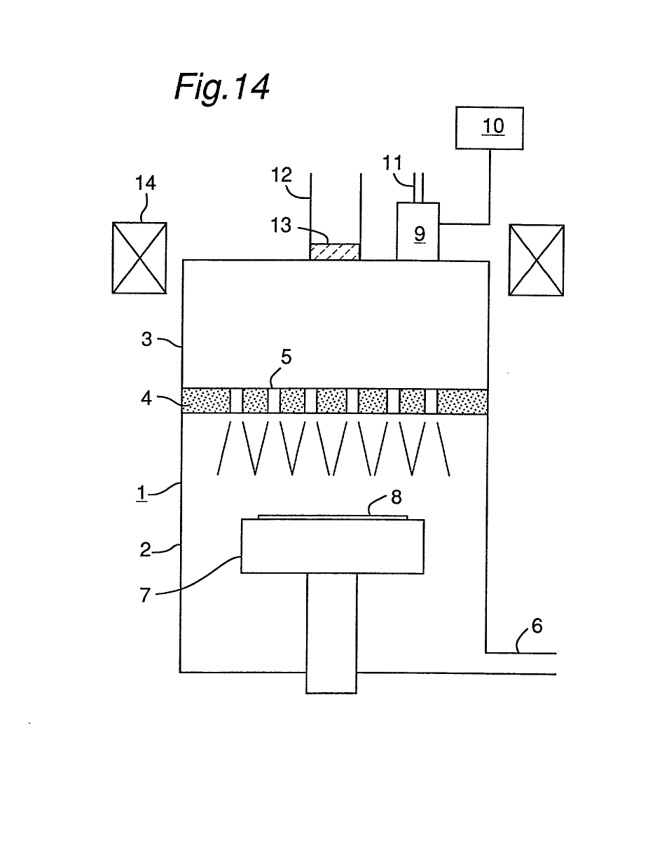

### DETAILED DESCRIPTION OF THE INVENTION

Preferred embodiments of the plasma processing apparatus according to the present invention will be described below with reference to the accompanying drawings.

Embodiment 1

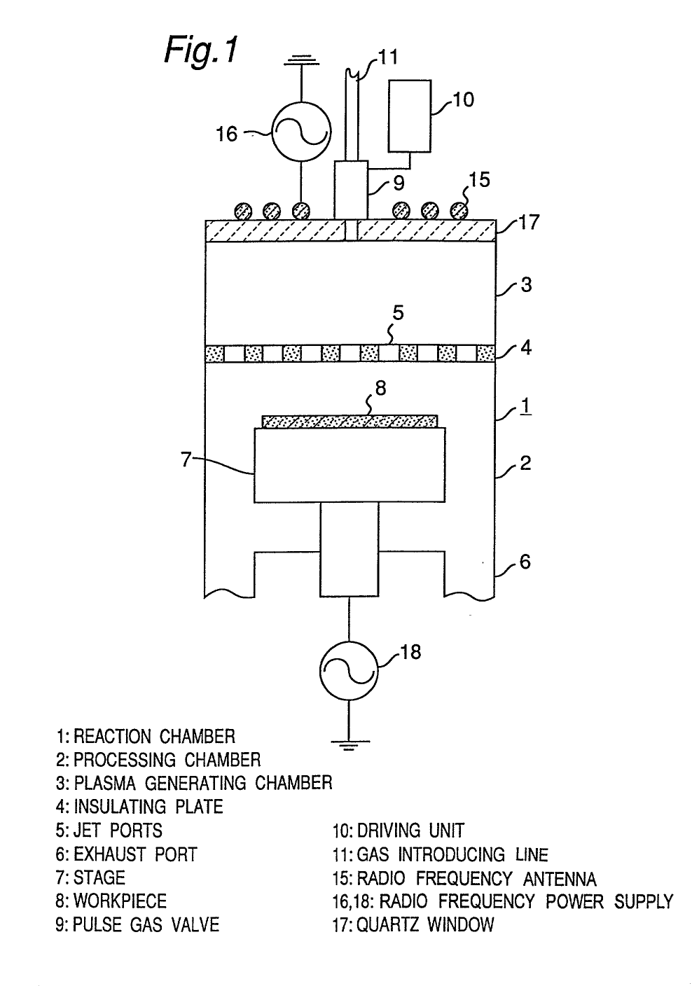

FIG. 1 is a schematic cross-sectional view of a plasma processing apparatus according to a first embodiment of the present invention. In FIG. 1, reference numeral 2 designates a processing chamber wherein a workpiece, for example a wafer 8 is processed with plasma, reference numeral 3 designates a plasma generating chamber wherein plasma is generated, and, in the present embodiment, reaction chamber 1 consists of these two chambers 2 and 3. Reference numeral 4 designates a partition plate for partitioning the processing chamber 2 from the plasma generating chamber 3, reference numeral 5 designates holes which are provided in the partition plate 4 and make the processing chamber 2 in connection with the plasma generating chamber 3, reference numeral 6 designates a exhaust port, reference numeral 7 designates a stage, and reference numeral 9 designates a pulse gas valve which is a gas supplying means to pulsatively supply the gases to the plasma generating chamber 3. Reference numeral 10 designates a drive means for the pulse gas valve 9, reference numeral 11 designates a gas introducing line, reference numeral 15 designates a radio frequency antenna, reference numeral 16 designates a radio frequency power supply, and reference numeral 17 designates a quartz window.

In the present embodiment, the reaction chamber 1 is shaped in a cylindrical form having, for example, a diameter of 40 to 50 cm and a height of 20 to 30 cm. The stage 7 is shaped in a columnar form or a disc form and is arranged coaxially with the reaction chamber 1. In the present embodiment, the shapes of the reaction chamber I and the stage 7 are not limited to cylindrical form, columnar form or disc form, however it is preferable that their shapes are axially symmetrical for uniform processing.

Further, in the present embodiment, the pulse gas valve 9 is arranged coaxially with the central axis of the reaction chamber 1 and the exhaust port 6 in an annular or ring shape is also arranged coaxially with the central axis of the reaction chamber 1. In the present embodiment, the exhaust port 6 may not be in a contiguous ring shape, but may consists of a plurality of small ports, wherein each small port is arranged concentrically around the central axis of the reaction chamber 1.

In the plasma processing apparatus having the constitution as described above, the drive means 10 actuates the pulse gas valve 9 and then the processing gas is pulsatively introduced into the plasma generating chamber 3. When a radio frequency voltage is applied to the radio frequency antenna 15 by the radio frequency power supply 16, an electromagnetic field is formed within the plasma generating chamber 3 through the quartz window 17. Then, inductively coupled plasma (ICP) is generated within the plasma generating chamber 3. The generated plasma and neutral radicals are transported to the processing chamber 2 through the holes 5 in the partition plate 4. Then, the plasma and the neutral radicals become incident on (or strike) the surface of wafer 8 as a supersonic free jet caused by the pressure difference between the plasma generating chamber 3 and the processing chamber 2 and the intended processing are achieved. And then, the neutral radicals and the reaction products produced by the wafer processing are exhausted through the exhaust ports 6.

The plasma processing apparatus according to the present invention is characterized in that one or more processing gases are supplied by using the pulse gas valve 9, and plasma and neutral radicals are jetted into the processing chamber 2 as a supersonic free jet making use of the pressure difference between the plasma generating chamber 3 and the processing chamber 2.

In general, a gas flow becomes a supersonic free jet under the condition as shown in Formula (1) as follows:

$$\frac{{P}_{1}}{{P}_{2}} > {( \frac{γ + 1}{2} )}^{γ / ( γ - 1 )} \qquad ( 1 )$$

The Mach disk of the supersonic free jet resides in the position shown as follows:

$$\frac{{x}_{d}}{d} = 0.67 \sqrt{\frac{{P}_{1}}{{P}_{2}}} \qquad ( 2 )$$

In the above formulae (1) and (2), P₁ represents a pressure of a gas storage container, P₂ represents a pressure of a container from which the gases are jetted out, γ represents a ratio of specific heat of the gases, X_{M} represents a position of the Mach disk of the supersonic free jet, and d represents a diameter of the nozzle. Since the hole of the nozzle is circular, the supersonic free jet is an axially symmetrical flow. In the present embodiment, P₁ represents a pressure of the plasma generating chamber 3 and P₂ represents a pressure of the processing chamber 2.

According to formula (2), at the instant when the processing gases are supplied through the pulse gas valve 9, the Mach disk of the supersonic free jet (X_{M}) reaches a point which is thousands times of the nozzle diameter distant. Therefore, neutral radicals almost instantly reach the surface of the workpiece 9. However, when the pulse gas valve 9 is closed, the pressure difference decreases and the value of XM decreases. And when the pressure difference comes to not satisfy the condition of the formula (1), the gas flow becomes to a general flow.

In the present embodiment, since a constitution that the pulse gas valve 9 is arranged coaxially with the central axis of the reaction chamber 1 and the exhaust port 6 is also arranged axially symmetrical with respect to the central axis of the reaction chamber 1 is employed, even if a supersonic free jet is not formed, the gas flow and pressure from the pulse gas valve 9 to exhaust port 6 may be unified, so that a uniform processing over the wafer 8 may be achieved.

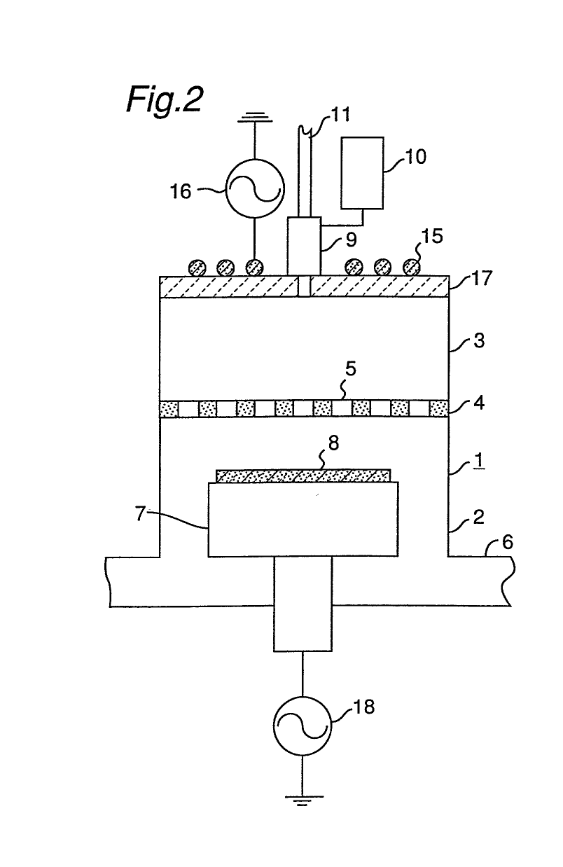

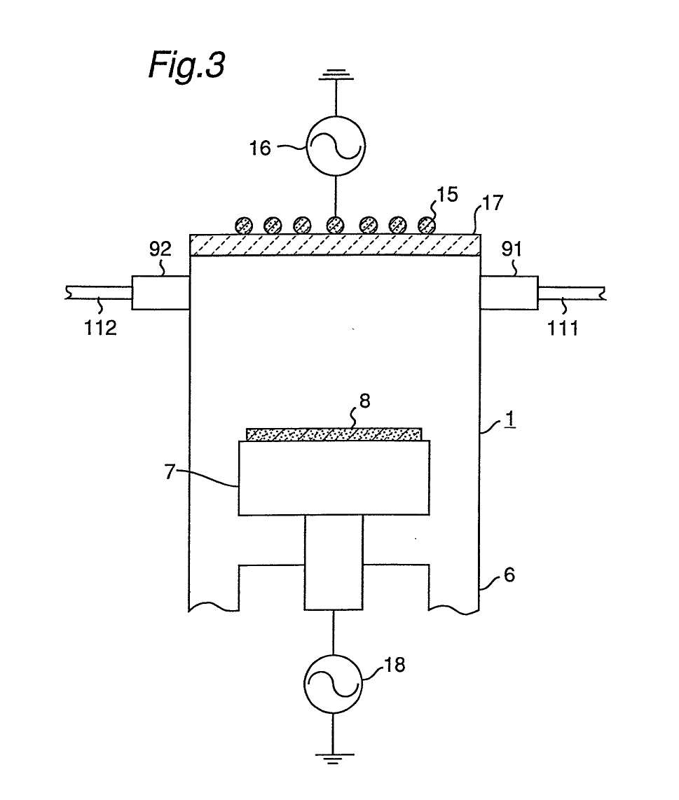

In the embodiment shown in FIG. 1, the gas supplying direction by the pulse gas valve 9 was arranged to correspond with the exhausting direction by said exhausting means. However, the arrangement is not necessarily limited as above, but may be changed such a manner that the gases are axially introduced into the reaction chamber 1 from the top portion thereof and the exhausting direction is directed to a direction perpendicular to the axis of the reaction chamber 1 as shown in FIG. 2. Alternatively, the other arrangements may be employed, one of which is that the gases are introduced in the direction perpendicular to the axis of the reaction chamber 1 from the sidewall and the exhausting direction is arranged to correspond with the axis of the reaction chamber 1 as shown in FIG. 3, and another is that the gases are introduced in the direction perpendicular to the axis of the reaction chamber 1 and the exhausting direction is also directed to the direction perpendicular to the axis of the reaction chamber 1, not shown in the drawings. In FIG. 3, reference numerals 91 and 92 designate the pulse gas valves respectively, and reference numerals 111 and 112 designate the gas introducing conduits respectively. In the embodiment of FIG. 3, two pulse gas valves 91 and 92 are arranged in the reaction chamber 1 so that the two valves are axially symmetrical with respect to the central axis of the reaction chamber 1. In addition, the both drive means for the pulse gas valves 91 and 92 are not shown in FIG. 3.

The present embodiment is described as to the apparatus having the partition plate 4, however, the same explanation is applicable to the arrangement that does not have the partition plate 4 and both plasma generation and plasma processing are performed in the same reaction chamber 1.

Embodiment 2

Then, a next embodiment will be explained, wherein the pulse gas valve 9 and the exhaust port 6 are not coaxially arranged with the central axis of the reaction chamber 1 or they are not arranged in a position axially symmetrical with respect to the central axis of the reaction chamber 1.

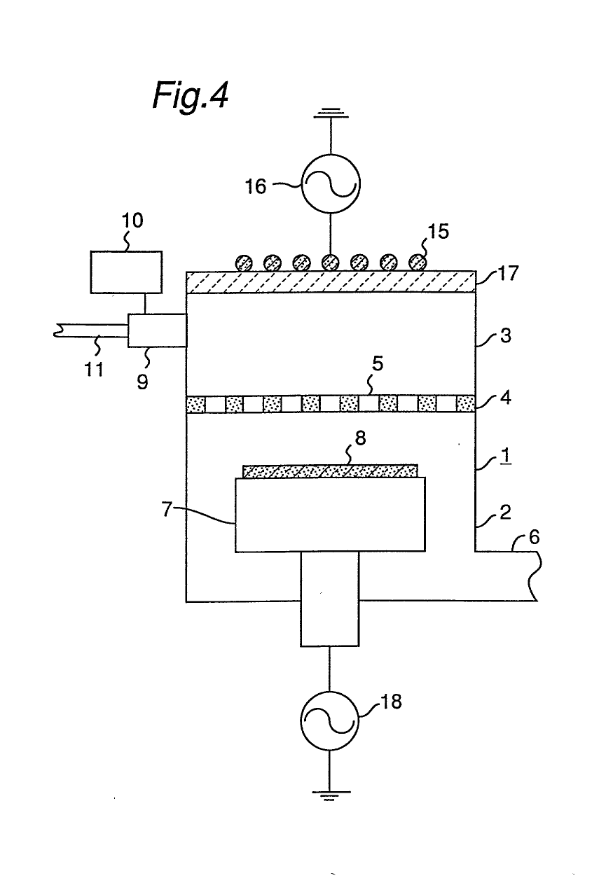

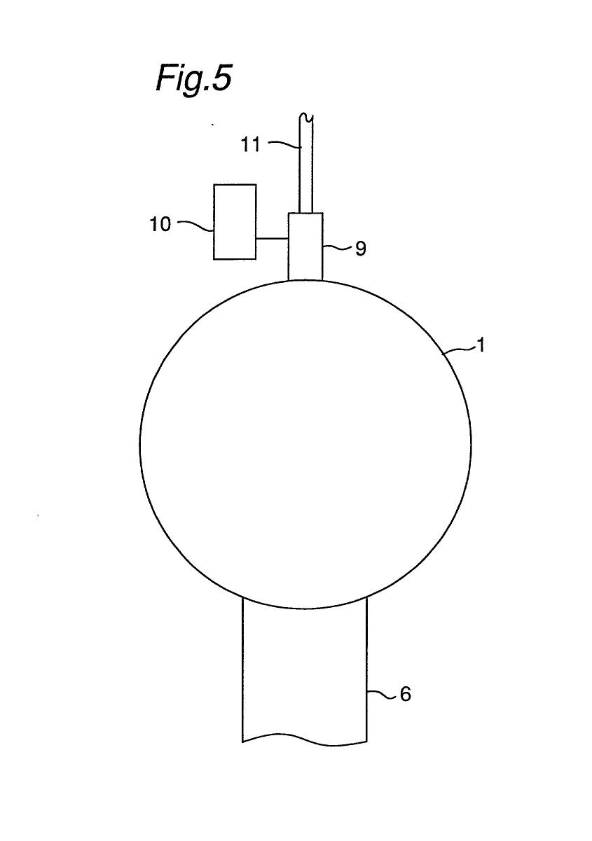

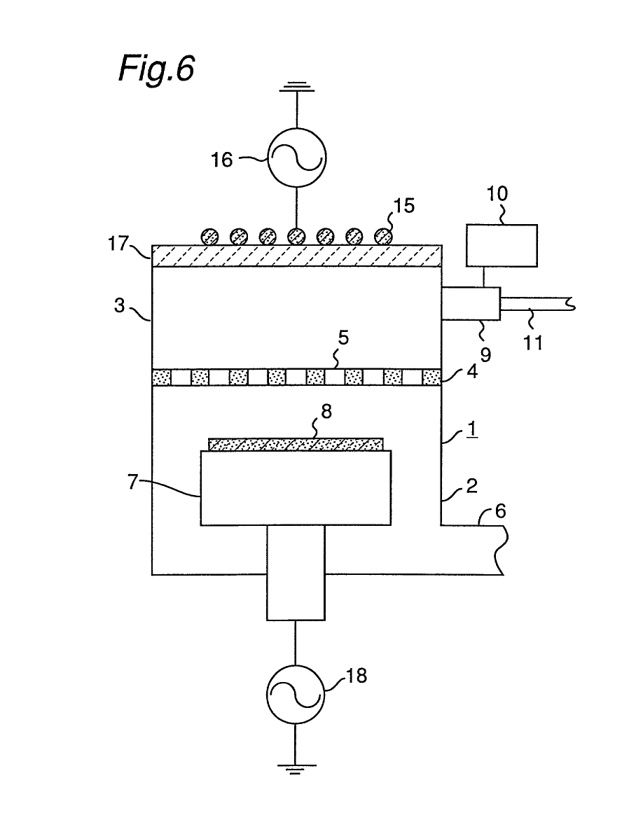

FIGS. 4 and 5 are schematic cross-sectional views of a plasma processing apparatus according to a second embodiment of the present invention, wherein FIG. 4 is a schematic cross-sectional view and FIG. 5 is a plan view. FIG. 6 is a schematic cross-sectional view of a plasma processing apparatus wherein a connecting position of a pulse gas valve is changed in comparison to the second embodiment of the present invention. In the present embodiment, the pulse gas valve 9 and the exhausting port 6 are provided in the sidewall of the reaction chamber 1, and the gas supplying direction by the pulse gas valve 9 is arranged to correspond with the exhausting direction by said exhausting port 6. Further, as shown in FIG. 5, when observed from the direction perpendicular to the face to be processed of the wafer 8, the gas supplying direction by the pulse gas valve 9 is arranged to direct the center of the reaction chamber 1 and the arrangement and the exhausting direction of the exhausting port 6 is arranged to correspond with the gas supplying direction. To the contrary, in the comparative embodiment as shown in FIG. 6, the gas supplying direction by the pulse gas valve 9 is arranged opposite to the exhausting direction by the exhausting port 6.

Now, examples of etching process of substrates performed at the following condition, using the apparatuses according to the present invention shown in FIGS. 4 and 5 and that of in the comparative embodiment shown in FIG. 6 is described. In such processing, a substrate of a silicon substrate with an oxide film, and a substrate consisting of the above substrate, onto which a polycrystalline silicon is further deposited are used.

| Etching condition: | | |
|---|---|---|
| Opening time of the pulse gas valve: | 20 | msec., |
| Closing time of the pulse gas valve: | 280 | msec., |
| mean flow rate of chlorine gas: | 150 | sccm, |
| mean pressure in the processing chamber: | 3 | mTorr, |
| Applied power to RF frequency antenna: | 1800 | W, |
| Applied RF bias power to substrate: | 30 | W. |

As to the substrate on which polycrystalline silicon is deposited, the uniformity of the etch rate was ±7% when the apparatus constitution according to the present embodiment was used. To the contrary, it was ±18% when the apparatus constitution according to the comparative embodiment was used. As to the substrate on which only oxide film is deposited, the uniformity of the etch rate was ±5% in both cases when the apparatus constitution according to the present embodiment was used and when the apparatus constitution according to the comparative embodiment was used. According to this result, although the gas flow and the pressure distribution scarcely exert an influence upon the etching of the material such as oxide film where ion bombardment etching reaction is dominant in the etching mechanism thereof, they exert no little influence upon the etching of the material such as polycrystalline silicone where neutral radical species exert much influence upon the etching processing. Therefore, in such processing, it is found that the apparatus according to the present embodiment achieves more uniform processing. Further, in the above test, the uniformity of the etch rate was determined as follows:

The difference of the film thickness before and after etching processing was measured at one point and divided by the processing time to obtain the processing rate;

Such a measurement is made at 49 points; and

Statistical variation thereof is calculated.

Using the apparatus constitution where the pulse gas valve 9 is arranged on the sidewall of the plasma generating chamber 3, when a switching operation (opening and closing operation) of the pulse gas valve 9 is performed, the gases diffuse throughout the plasma generating chamber 3 as a supersonic free jet according to the above formula (2) at the instant when the pulse gas valve 9 is opened. However, when the pulse gas valve 9 is closed and the condition shown in the above formula (1) is not satisfied, the gas flow comes to a usual free molecular flow or Knudsen flow. Then the pressure distribution within the plasma generating chamber 3 becomes uneven, as a result, the pressure distribution within the processing chamber 2 becomes uneven. Accordingly, the distribution of neutral radicals and reaction product comes to uneven within the processing chamber 2, so that etching processing comes to not uniform. Although in the case that an arrangement where the pulse gas valve 9 and the exhausting port 6 are coaxially arranged with the central axis of the reaction chamber 1 as in the embodiment 1 is not employed, even if a supersonic free jet is not formed, the deviation or unevenness of pressure and gas flow may be decreased by employing an arrangement where the gas supplying direction by the pulse gas valve 9 is arranged to correspond with the exhausting direction by said exhausting port 6, and further, as shown in FIG. 5, when observed from the direction perpendicular to the face to be processed of the wafer 8, the gas supplying direction by the pulse gas valve 9 is arranged to direct the center of the reaction chamber 1, and the arrangement and the exhausting direction of the exhausting port 6 is arranged to correspond with the gas supplying direction as the present embodiment.

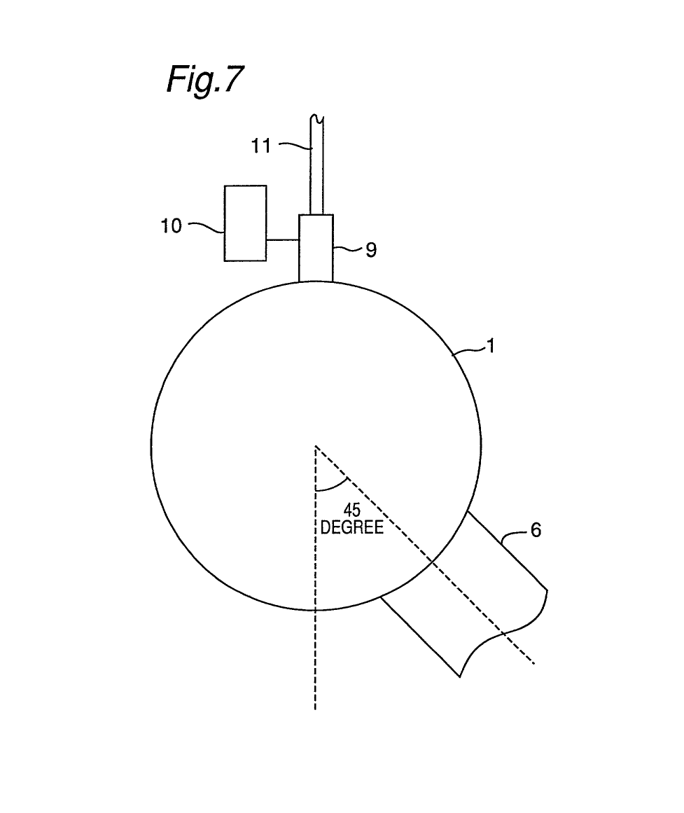

Although the embodiment where the gas supplying direction by the pulse gas valve 9 is arranged to direct the center of the reaction chamber 1 and the arrangement and the exhausting direction of the exhausting port 6 is arranged to correspond with the gas supplying direction is shown in FIG. 5, almost the same effect may be obtained when the exhausting ports are arranged in the reaction chamber 1 so that a line extending from the center of the reaction chamber 1 to the exhausting ports is oriented at an angle from −45 degree to +45 degree relative to a line from the gas supplying means to the center of the reaction chamber 1 and the exhausting direction by the exhausting means from the center of the reaction chamber 1 is also oriented at the same angle as above when observed from the direction perpendicular to the face to be processed of the wafer as shown in FIG. 7.

The present embodiment is described as to the apparatus having the partition plate 4, however, the same explanation is applicable to the arrangement that does not have the partition plate 4 and both plasma generation and plasma processing are performed in the same reaction chamber 1.

Embodiment 3

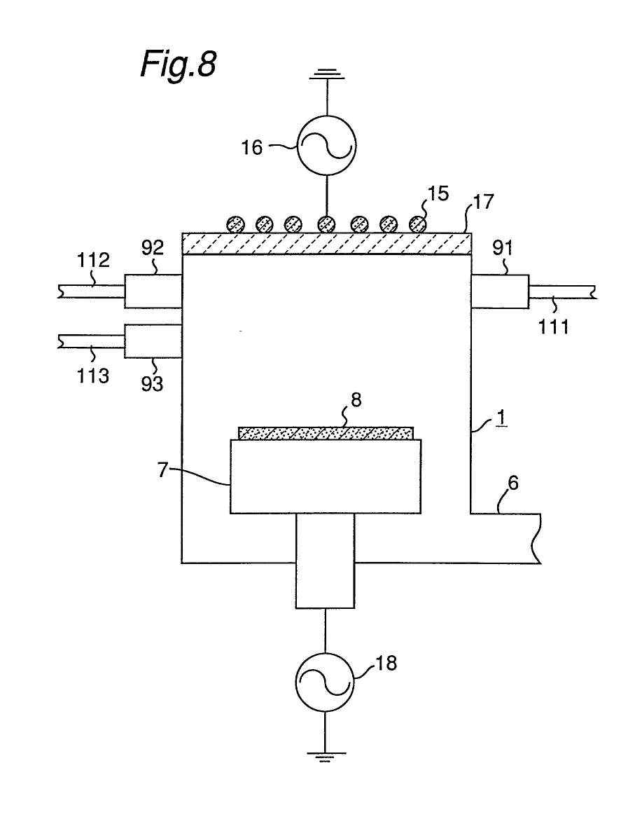

FIG. 8 is a schematic cross-sectional view of a plasma processing apparatus according to a third embodiment of the present invention. In FIG. 8, reference numeral 93 designates a pulse gas valve and reference numeral 113 designates a gas introducing line. In addition, each drive means for each pulse gas valve 91, 92 and 93 is not shown in FIG. 8. In the present embodiment, one pulse gas valve 91 is connected to the proximity of the exhaust means 6 and two pulse gas valves 92 and 93 are connected to the opposite side of the exhaust means 6.

According to the above constitution, since the gas flow rates are increased in the region apart from the exhaust means 6 due to the pulse gas valves 92 and 93, the deviation or unevenness of pressure and gas flow within the reaction chamber 1 may be prevented due to attaining a balance with the exhaust. Therefore, even if a supersonic free jet is not formed, a uniform processing over the wafer can be achieved. In addition, since a plurality of pulse gas valves 91, 92 and 93 are connected, such a constitution is useful for the case wherein a plurality kinds of gases are used.

In the present embodiment, the number of the pulse gas valves to be connected to the reaction chamber 1 is not limited to three. The important feature of the present embodiment is that a relatively small number of the pulse gas valves is arranged in the proximity of the exhaust port 6 and the number thereof is increased as the distance from the exhaust port 6 increases. Therefore, almost the same effect is obtained by employing a constitution that the amount of the gases supplied by the gas supplying means is set relatively small in the proximity of the exhaust ports 6 and the amount of the gases supplied by the gas supplying ports 6 is increased at a position where its distance from the exhaust means increases.

In FIG. 8, an embodiment wherein the apparatus has no partition plate, however, the same effect may be obtained when an apparatus having the partition plate.

### Embodiment 4

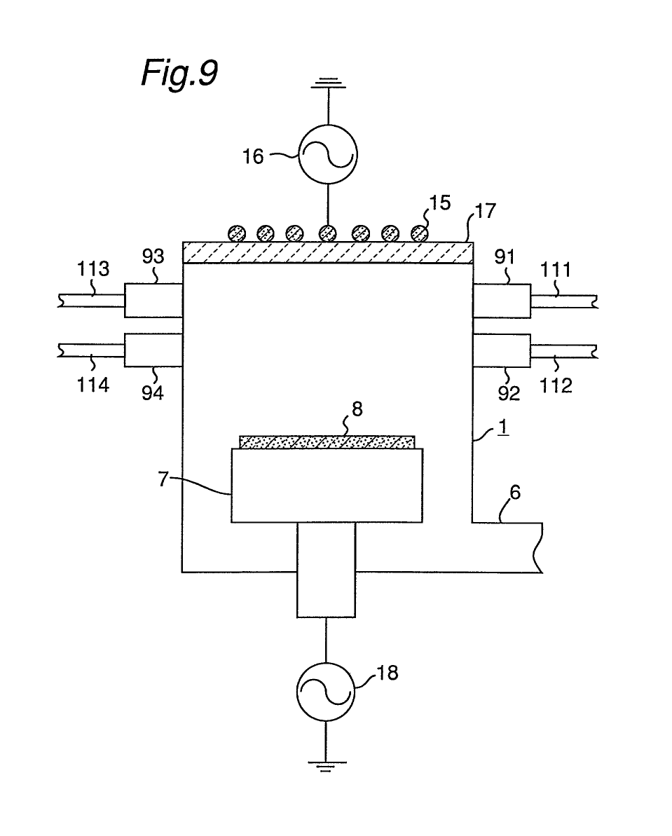

FIG. 9 is a schematic cross-sectional view of a plasma processing apparatus according to a fourth embodiment of the present invention. In FIG. 9, reference numeral 94 designates a pulse gas valve and reference numeral 114 designates a gas introducing line. In addition, each drive means for each pulse gas valve 91, 92, 93 and 94 is not shown in FIG. 9. In the present embodiment, each of a plurality of pulse gas valves may be arranged to be connected to the sidewall of the reaction chamber 1 at optional position, respectively. For example, two valves are arranged in the proximity of the exhaust port 6 and the other two valves are arranged at the opposite side of the exhaust port 6. Then, the gas flow rates in the pulse gas valves 93 and 94 which are positioned apart from the exhaust port 6 are relatively increased and that in the valves 91 and 92 which are positioned in the proximity of the exhaust port 6 are relatively decreased. Thus, a constitution can be achieved, wherein the amount of the gases supplied by the pulse gas valve is made relatively small in the proximity of the exhaust port 6 and the amount is increased as the distance from the exhaust port 6 increases. Accordingly, even if a supersonic free jet is not formed, a uniform processing over the wafer may be achieved, preventing deviation or unevenness of pressure and gas flow within the reaction chamber 1. In addition, as in the case of the third embodiment, it is useful for the case wherein a plurality kinds of gases are used.

In FIG. 9, an embodiment wherein the apparatus has no partition plate, however, the same effect may be obtained when an apparatus having the partition plate.

Embodiment 5

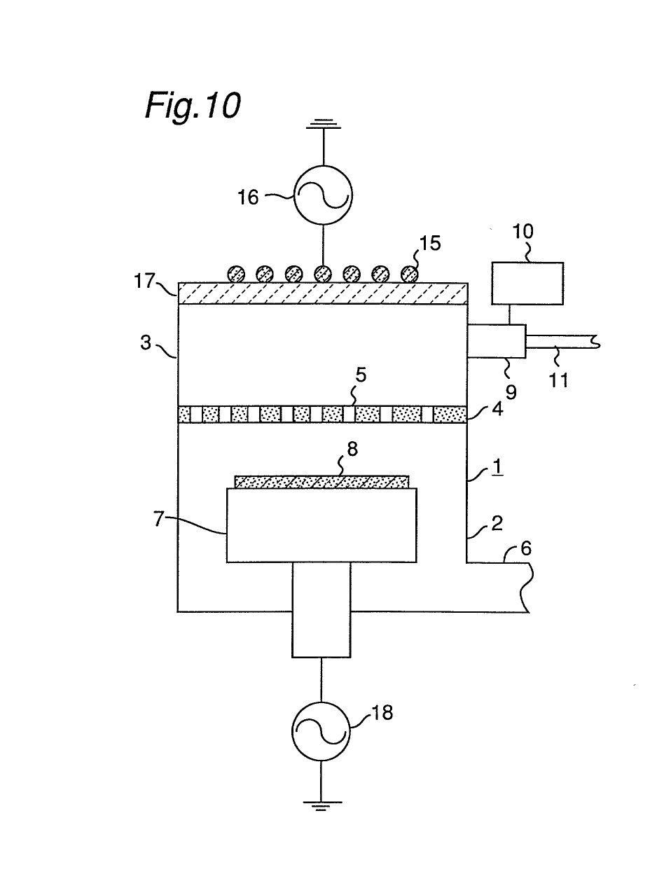

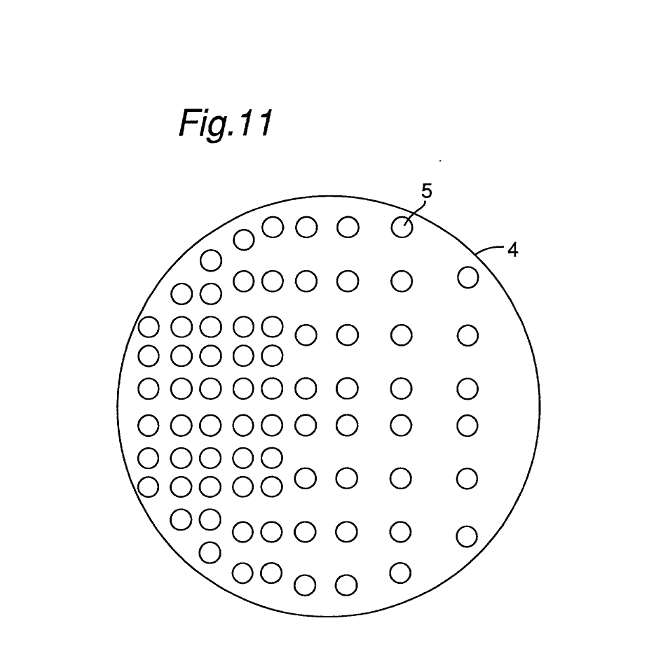

FIG. 10 is a schematic cross-sectional view of a plasma processing apparatus according to a fifth embodiment of the present invention and FIG. 11 is a schematic enlarged plan view showing the partition plate shown in FIG. 10. In the present embodiment, a number of the holes 5 is set at a relatively small figure in the proximity of the exhaust port 6 and the number of the holes 5 is increased at a position where its distance from the exhaust port 6 increases. Accordingly, an opening ratio of the holes 5, which means numbers of holes per unit area, is set small in the proximity of the exhaust port 6 and is set to increase as the distance from the exhaust port 6 increases. Therefore, even if a supersonic free jet is not formed, it is possible to achieve a uniform transferring rate or speed of the plasma gas from the plasma generating chamber 3 to the processing chamber 2, so that deviation or unevenness of pressure and gas flow within the reaction chamber 1 can be prevented. Accordingly, a uniform processing over the wafer 8 can be achieved.

Embodiment 6

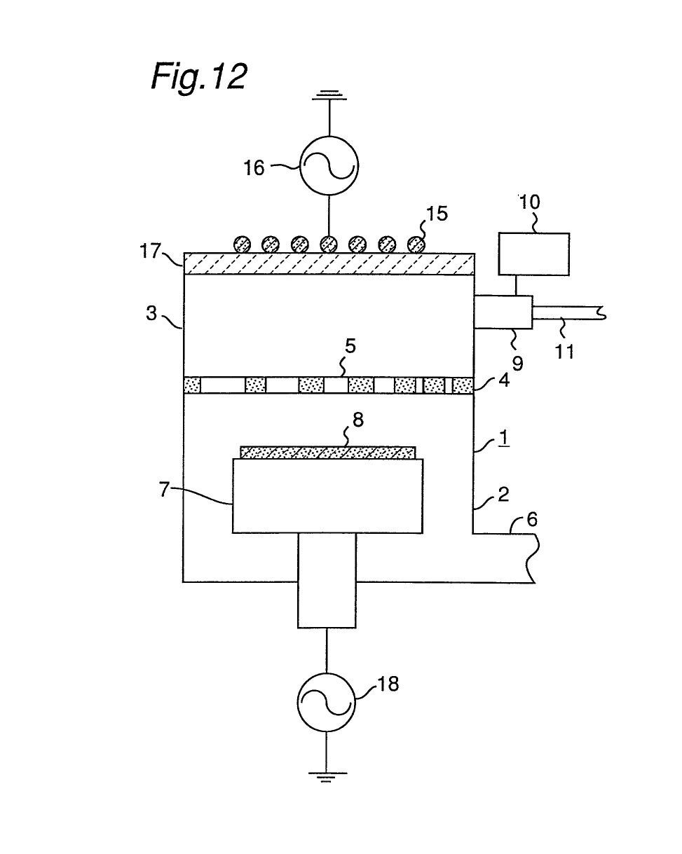

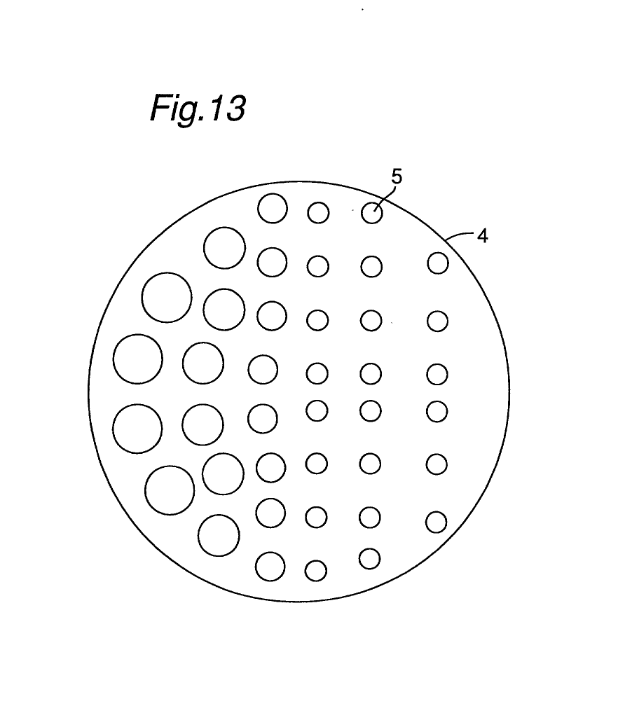

FIG. 12 is a schematic cross-sectional view of a plasma processing apparatus according to a sixth embodiment of the present invention and FIG. 13 is a schematic enlarged plan view showing the partition plate shown in FIG. 12. In the present embodiment, a diameter of a hole 5 is set at a relatively small figure in the proximity of the exhaust port 6 and a diameter of the hole 5 is relatively increased at a portion where its distance from the exhaust port 6 relatively increases. Accordingly, the opening ratio of the holes 5 is set small in the proximity of the exhaust port 6 and is set to increase at a portion where its distance from the exhaust port increases. Therefore, even if a supersonic free jet is not formed, it is possible to achieve a uniform transferring rate or speed of the plasma gas from the plasma generating chamber 3 to the processing chamber 2, so that deviation or unevenness of pressure and gas flow within the reaction chamber 1 may be prevented. Accordingly, a uniform processing over the wafer 8 may be achieved.

In the above fifth and sixth embodiments, a straightening vane for exhaustion may be arranged around the stage 7.

It should be understood by those skilled in the art that the arrangements and figures described in the above embodiments are not limited to the specific details and representative embodiments but presented for explanation only, and various modifications thereof are contemplated as necessary within the scope of the invention.

What is claimed is:

1. A plasma processing apparatus comprising a reaction chamber for processing a workpiece with plasma which is generated by using one or more gases, a gas supplying means which pulsatively supplies the gases to the reaction chamber, and an exhaust means for exhausting the reaction chamber, wherein a gas supplying direction by said gas supplying means is arranged to correspond with an exhausting direction by said exhausting means.

2. The plasma processing apparatus according to claim 1, wherein when observed from a direction perpendicular to a face of the workpiece to be processed, the gas supplying direction by said gas supplying means directs to a center of the reaction chamber, and the exhausting means are arranged in the reaction chamber so that an assumed straight line extending from the center of the reaction chamber to the exhausting means is oriented at an angle from −45 degree to +45 degree relative to a line from the gas supplying means to the center of the reaction chamber and the exhausting direction by the exhausting means from the center of the reaction chamber is also oriented at the same angle as above.

3. A plasma processing apparatus comprising a reaction chamber for processing a workpiece with plasma which is generated by using one or more gases, a gas supplying means which pulsatively supply the gases to the reaction chamber, and one or more exhaust means for exhausting the reaction chamber, wherein the shape of the reaction chamber is axially symmetrical with respect to an central axis of the reaction chamber, the gas supplying means are arranged on the central axis or at axially symmetrical positions with respect to the central axis of the reaction chamber, and the exhaust means are also arranged at axially symmetrical positions with respect to the central axis of the reaction chamber.

4. A plasma processing apparatus comprising a reaction chamber for processing a workpiece with plasma which is generated by using one or more gases, a gas supplying means which pulsatively supplies the gases to the reaction chamber, and an exhaust means for exhausting the reaction chamber, wherein the amount of the gases supplied by the gas supplying means is set relatively small in the proximity of the exhaust means and the amount of the gases supplied by the gas supplying means is increased at a position where its distance from the exhaust means increases.

5. The plasma processing apparatus according to claim 4, wherein a number of the gas supplying means is set relatively small in the proximity of the exhaust means and the number of the gas supplying means is increased at a position where its distance from the exhaust means increases.

6. The plasma processing apparatus according to claim 4, wherein the gas flow rate is set at a relatively small figure in the proximity of the exhaust means and the figure of the gas flow rate is increased at a position where its distance from the exhaust means increases.

7. The plasma processing apparatus comprising a reaction chamber for processing a workpiece with plasma which is generated by using one or more gases, a gas supplying means which pulsatively supplies the gases to the reaction chamber, an exhaust means for exhausting the reaction chamber, a partition plate which partitions the plasma generating chamber wherein plasma is generated from the processing chamber wherein a workpiece is processed with the plasma, and holes which are provided in the partition plate and make the processing chamber in connection with the plasma generating chamber, wherein at least one of the number and the size of the holes is changed depending on the distance thereof from the exhausting means, thereby an opening ratio of the holes being set at a relatively small figure in the proximity of the exhaust port and the figure thereof being relatively increased at a position where its distance from the exhaust means relatively increases.

8. The plasma processing apparatus according to claim 7, wherein a number of the holes is set at a relatively small figure in the proximity of the exhaust port and the number of the holes is relatively increased at a position where its distance from the exhaust means relatively increases.

9. The plasma processing apparatus according to claim 7, wherein a size of the hole is set at a relatively small figure in the proximity of the exhaust port and the size of the hole is relatively increased at a position where its distance from the exhaust means relatively increases.
